(19) United States
(12) Patent Application Publication
(10) Pub. No.: US 2015/0263101 A1
(43) Pub. Date: Sep. 17, 2015

(54) SEMICONDUCTOR DEVICE AND METHOD OF MANUFACTURING SAME

(71) Applicant: Kabushiki Kaisha Toshiba, Tokyo (JP)

(72) Inventors: Shingo Masuko, Ishikawa Kanazawa (JP); Takaaki Yasumoto, Kawasaki Kanagawa (JP); Naoko Yanase, Inagi Tokyo (JP); Miki Yumoto, Kawasaki Kanagawa (JP); Masahito Mimura, Togane Chiba (JP); Yasunobu Saito, Nomi Ishikawa (JP); Akira Yoshioka, Nomi Ishikawa (JP); Hidetoshi Fujimoto, Kawasaki Kanagawa (JP); Takeshi Uchihara, Kawaguchi Saitama (JP); Tetsuya Ohno, Nomi Ishikawa (JP); Toshiyuki Naka, Nonoichi Ishikawa (JP); Tasuku Ono, Nonoichi Ishikawa (JP)

(21) Appl. No.: 14/482,258

(22) Filed: Sep. 10, 2014

(30) Foreign Application Priority Data
Mar. 12, 2014 (JP) 2014-049252

(51) Int. Cl. H01L 29/20; H01L 21/78; H01L 29/66; H01L 21/306; H01L 29/778; H01L 23/12

(52) U.S. Cl. CPC H01L 29/2003; H01L 29/7787; H01L 23/12; H01L 29/66462; H01L 21/30612; H01L 21/78

(57) ABSTRACT

In one embodiment, a semiconductor device includes a semiconductor chip including a nitride semiconductor layer, and including a control electrode, a first electrode and a second electrode provided on the nitride semiconductor layer. The device further includes a support including a substrate, and including a control terminal, a first terminal and a second terminal provided on the substrate. The semiconductor chip is provided on the support such that the control electrode, the first electrode and the second electrode face the support. The control electrode, the first electrode and the second electrode of the semiconductor chip are electrically connected to the control terminal, the first terminal and the second terminal of the support, respectively.

### CROSS REFERENCE TO RELATED APPLICATION

This application is based upon and claims the benefit of priority from the prior Japanese Patent Application No. 2014-49252, filed on Mar. 12, 2014, the entire contents of which are incorporated herein by reference.

### FIELD

Embodiments described herein relate to a semiconductor device and a method of manufacturing the same.

### BACKGROUND

A nitride semiconductor device is expected to be a semiconductor device that can simultaneously realize the improvement in breakdown voltage and the reduction in on-resistance of a transistor because a nitride semiconductor has an excellent material characteristic. For example, a field effect transistor having a hetero interface between a gallium nitride (GaN) layer and an aluminum gallium nitride (AlGaN) layer receives attention. However, when a gate electrode, a source electrode and a drain electrode provided on the nitride semiconductor layer of the nitride semiconductor device are electrically connected to a gate terminal, a source terminal and a drain terminal of a package of the nitride semiconductor device through bonding wires respectively, there is a problem that it is difficult to supply a large current and a high voltage to the nitride semiconductor device or to release the heat of the nitride semiconductor device from the bonding wires because the bonding wires are thin. Also, when potential of a substrate in a semiconductor chip of the nitride semiconductor device gets into a floating state, there is a problem that the collapse of the semiconductor chip is generated due to the lattice mismatch between the substrate and the nitride semiconductor layer.

### BRIEF DESCRIPTION OF THE DRAWINGS

FIG. 1 is a cross-sectional view illustrating a structure of a semiconductor device of a first embodiment;

FIG. 2 is a plan view illustrating the structure of the semiconductor device of the first embodiment; and

FIGS. 3A to 4C are cross-sectional views illustrating a method of manufacturing the semiconductor device of the first embodiment.

### DETAILED DESCRIPTION

Embodiments will now be explained with reference to the accompanying drawings.

In one embodiment, a semiconductor device includes a semiconductor chip including a nitride semiconductor layer, and including a control electrode, a first electrode and a second electrode provided on the nitride semiconductor layer. The device further includes a support including a substrate, and including a control terminal, a first terminal and a second terminal provided on the substrate. The semiconductor chip is provided on the support such that the control electrode, the first electrode and the second electrode face the support. The control electrode, the first electrode and the second electrode of the semiconductor chip are electrically connected to the control terminal, the first terminal and the second terminal of the support, respectively.

### First Embodiment

### (1) Structure of Semiconductor Device of First Embodiment

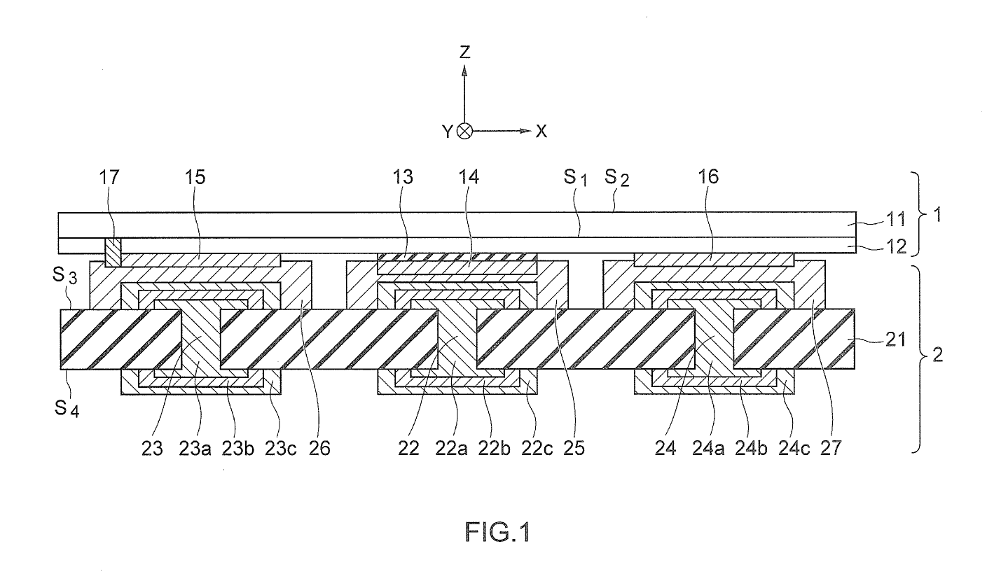

FIG. 1 is a cross-sectional view illustrating a structure of a semiconductor device of a first embodiment. The device of FIG. 1 is a nitride semiconductor device including a semiconductor chip 1 and a support 2.

The semiconductor chip 1 includes a semiconductor substrate 11 as an example of a substrate, a nitride semiconductor layer 12, a gate insulator 13, a gate electrode 14 as an example of a control electrode, a source electrode 15 and a drain electrode 16 as examples of first and second electrodes, and a post electrode 17 as an example of one or more electrodes.

The support 2 includes a support substrate 21 as an example of a substrate, a gate terminal 22 as an example of a control terminal, a source terminal 23 and a drain terminal 24 as examples of first and second terminals, and solders 25, 26 and 27.

The semiconductor substrate 11 is, for example, a silicon (Si) substrate. The semiconductor substrate 11 includes a first face S₁, and a second face S₂ opposite to the first face S₁. The support substrate 21 is, for example, an insulating substrate such as an aluminum nitride (AlN) substrate. The support substrate 21 includes a first face S₃, and a second face S₄ opposite to the first face S₃.

FIG. 1 illustrates an X direction and a Y direction that are parallel to the semiconductor substrate 11 and the support substrate 21 and are perpendicular to each other, and a Z direction that is perpendicular to the semiconductor substrate 11 and the support substrate 21. In this specification, a +Z direction is handled as an upper direction, and a −Z direction is handled as a lower direction. For example, the positional relationship between the semiconductor substrate 11 and the support substrate 21 is expressed that the support substrate 21 is placed below the semiconductor substrate 11.

The nitride semiconductor layer 12 is formed on the first face S₁ of the semiconductor substrate 11. The nitride semiconductor layer 12 is a semiconductor layer including nitrogen. The nitride semiconductor layer 12 is, for example, a stack film including a buffer layer, an electron transit layer and an electron supply layer. An example of the buffer layer is a stack film including an AlN layer, an AlGaN layer and a GaN layer. An example of the electron transit layer is a GaN layer. An example of the electron supply layer is an AlGaN layer.

The gate electrode 14, the source electrode 15 and the drain electrode 16 are formed on the first face S₁ of the semiconductor substrate 11 via the nitride semiconductor layer 12. Specifically, the gate electrode 14 faces the nitride semiconductor layer 12 via the gate insulator 13. The source electrode 15 and the drain electrode 16 contact the nitride semiconductor layer 12. An example of the gate insulator 13 is a silicon oxide film. An example of the gate electrode 14, the source electrode 15 and the drain electrode 16 is a stack film including a nickel (Ni) layer and a gold (Au) layer.

The post electrode 17 is formed on the first face S₁ of the semiconductor substrate 11 and electrically connects the source electrode 15 to the semiconductor substrate 11. The post electrode 17 of the present embodiment has a function of making the potential of the semiconductor substrate 11 same as the potential of the source electrode 15 (fixed potential) to prevent the potential of the semiconductor substrate 11 from getting into a floating state. This enables the present embodiment to suppress the generation of the collapse of the semiconductor chip 1 due to the lattice mismatch between Si of the semiconductor substrate 11 and GaN of the nitride semiconductor layer 12. An example of the post electrode 17 is a metal layer formed by a plating method. The connection between the post electrode 17 and the semiconductor substrate 11 may be an ohmic connection or a non-ohmic connection.

The gate terminal 22, the source terminal 23 and the drain terminal 24 are formed on the support substrate 21. Each of the gate terminal 22, the source terminal 23 and the drain terminal 24 includes a first conductive layer (for example, copper (Cu) layer) 22a, 23a, 24a, a second conductive layer (for example, nickel (Ni) layer) 22b, 23b, 24b, and a third conductive layer (for example, gold (Au) layer) 22c, 23c, 24c.

Each of the gate terminal 22, the source terminal 23 and the drain terminal 24 includes a first portion formed on the first face S₃ of the support substrate 21, a second portion formed on the second face S₄ of the support substrate 21, and a third portion electrically connecting the first portion to the second portion. The gate terminal 22, the source terminal 23 and the drain terminal 24 can be formed, for example, by forming plural holes penetrating the support substrate 21 and forming the gate terminal 22, the source terminal 23 and the drain terminal 24 in the holes.

The gate terminal 22, the source terminal 23 and the drain terminal 24 are used as external connection terminals of the semiconductor device of the present embodiment. For example, when it is necessary to electrically connect the gate electrode 14 of the semiconductor device of the present embodiment to an external device, the gate terminal 22 of the support substrate 21 on the second face S₄ is electrically connected to a terminal of the external device.

The semiconductor chip 1 is provided on the support 2 such that the gate electrode 14, the source electrode 15 and the drain electrode 16 face the support 2. In other word, the semiconductor chip 1 is provided on the support 2 in a state that the first face S₁ of the semiconductor substrate 11 and the first face S₃ of the support substrate 21 face each other. In this manner, the semiconductor chip 1 of the present embodiment is provided on the support 2 in a face-down state.

The semiconductor chip 1 is bonded to the support 2 with the solders 25 to 27. Specifically, the gate electrode 14 is bonded to the gate terminal 22 with the solder 25. The source electrode 15 is bonded to the source terminal 23 with the solder 26. The drain electrode 16 is bonded to the drain terminal 24 with the solder 27. As a result, the gate electrode 14, the source electrode 15 and the drain electrode 16 of the semiconductor chip 1 are electrically connected to the gate terminal 22, the source terminal 23 and the drain terminal 24 of the support 2, respectively. An example of material of the solders 25 to 27 is Sn—Ag—Cu.

The semiconductor chip 1 of the present embodiment is attached to the support 2 by forming the solders 25 to 27 on the support 2 and bonding the semiconductor chip 1 to the support 2 with the solders 25 to 27. However, the semiconductor chip 1 of the present embodiment may be attached to the support 2 by another method.

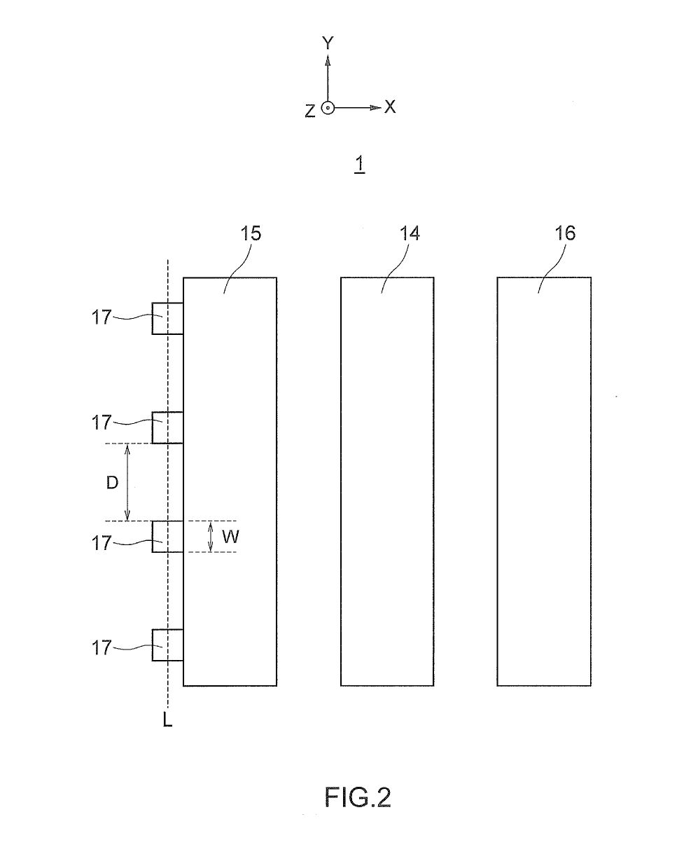

FIG. 2 is a plan view illustrating the structure of the semiconductor device of the first embodiment. FIG. 2 only illustrates the gate electrode 14, the source electrode 15, the drain electrode 16, and post electrodes 17 in the semiconductor chip 1 of the first embodiment, and omits the illustration of other components.

The gate electrode 14, the source electrode 15 and the drain electrode 16 have band shapes extending in the Y direction. The Y direction is an example of a first direction. The gate electrode 14 is placed between the source electrode 15 and the drain electrode 16.

The post electrodes 17 of the present embodiment are not placed on the gate electrode 14 side of the source electrode 15, but placed on the opposite side to the gate electrode 14 relative to the source electrode 15. Such placement of the post electrodes 17 has an advantage, for example, that a short of the gate electrode 14 and the post electrodes 17 can be prevented. The post electrodes 17 of the present embodiment are placed in a row on a straight line L parallel to the Y direction.

A reference sign D denotes the distance between the post electrodes 17 adjacent to each other in the Y direction. A reference sign W denotes the width of the post electrodes 17 in the Y direction. In the present embodiment, the distance D between the post electrodes 17 is set larger than the width W of the post electrodes 17. An example of the distance D is 100 μm, and an example of the width W is 10 μm.

The position and the shape of the post electrodes 17 may differ from the above example. The values of the distance D and the width W may differ from the above example. For example, although the post electrodes 17 of the present embodiment are placed at a regular interval, the post electrodes 17 may be placed at an irregular interval.

### (2) Details of Semiconductor Device of First Embodiment

Details of the semiconductor device of the first embodiment will be described with reference to FIG. 1 again.

As described above, the semiconductor chip 1 of the present embodiment is provided on the support 2 such that the gate electrode 14, the source electrode 15 and the drain electrode 16 face the support 2. Furthermore, the gate electrode 14, source electrode 15 and drain electrode 16 of the semiconductor chip 1 of the present embodiment are electrically connected to the gate terminal 22, source terminal 23 and drain terminal 24 of the support 2, respectively.

Accordingly, the present embodiment can electrically connect the gate electrode 14, the source electrode 15 and the drain electrode 16 to the gate terminal 22, the source terminal 23 and the drain terminal 24 respectively without using bonding wires.

Therefore, the present embodiment can readily supply a large current and a high voltage to the semiconductor device. As a result, the present embodiment makes it possible to efficiently use an advantage that the nitride semiconductor device has high breakdown voltage and low on-resistance.

The present embodiment can also readily release the heat of the semiconductor device from the gate terminal 22, the source terminal 23 and the drain terminal 24. As a result, when a large current or a high voltage is supplied to the nitride semiconductor device, a great deal of heat of the nitride semiconductor device can be released to the outside. The present embodiment can release the heat of the semiconductor device also from the support substrate 21.

When the electrodes 14 to 16 are connected to the terminals 22 to 24 through the bonding wires as in a conventional manner, there are problems that the positions of the bonding wires are fluctuated, that it is required to provide bonding pads on the semiconductor chip 1, and that the bonding wires inhibit the packaging of the semiconductor device (in other words, inhibit the downsizing of the semiconductor device).

However, the present embodiment makes it possible to surely fix the positions of the electrodes 14 to 16 and the terminals 22 to 24 by using the solders 25 to 27, for example. The present embodiment also makes it possible to reduce the area of the semiconductor chip 1 since it is not necessary to provide the bonding pads on the semiconductor chip 1. Furthermore, the present embodiment makes it possible to downsize the semiconductor device since the electrodes 14 to 16 can be placed close to the terminals 22 to 24.

Also, since the semiconductor chip 1 of the present embodiment is attached to the support 2 in a face-down state, the electrodes 14 to 16 are placed on the support 2 side, and the semiconductor substrate 11 is placed on the opposite side to the support 2. Accordingly, the floating state of the potential of the semiconductor substrate 11 is preferably avoided. Also, in the case where the semiconductor chip 1 includes the nitride semiconductor layer 12 like the present embodiment, the collapse due to the lattice mismatch between Si of the semiconductor substrate 11 and GaN of the nitride semiconductor layer 12 is preferably suppressed.

For these problems, the semiconductor device of the present embodiment includes the post electrodes 17 that electrically connect the source electrode 15 to the semiconductor substrate 11. Accordingly, the present embodiment can make the potential of the semiconductor substrate 11 same as the potential of the source electrode 15 to prevent the potential of the semiconductor substrate 11 from getting into a floating state. Therefore, the present embodiment makes it possible, by preventing the potential of the semiconductor substrate 11 from getting into the floating state, to suppress the collapse due to the lattice mismatch between the semiconductor substrate 11 and the nitride semiconductor layer 12.

In a case where the bonding wires are used to connect the electrodes 14 to 16 to the terminals 22 to 24 as in a conventional manner, there is a problem that it is difficult to mold the semiconductor device because it is necessary to mold the bonding wires with resins, and the positions of the bonding wires are fluctuated.

However, the present embodiment can readily mold the semiconductor device because it is not necessary to mold the bonding wires. Also, the present embodiment can adopt an implementation in which the semiconductor device is not molded because it is not necessary to mold the bonding wires. However, the semiconductor substrate 11 may be molded in the present embodiment to prevent the semiconductor substrate 11 from cracking.

### (3) Method of Manufacturing Semiconductor Device of First Embodiment

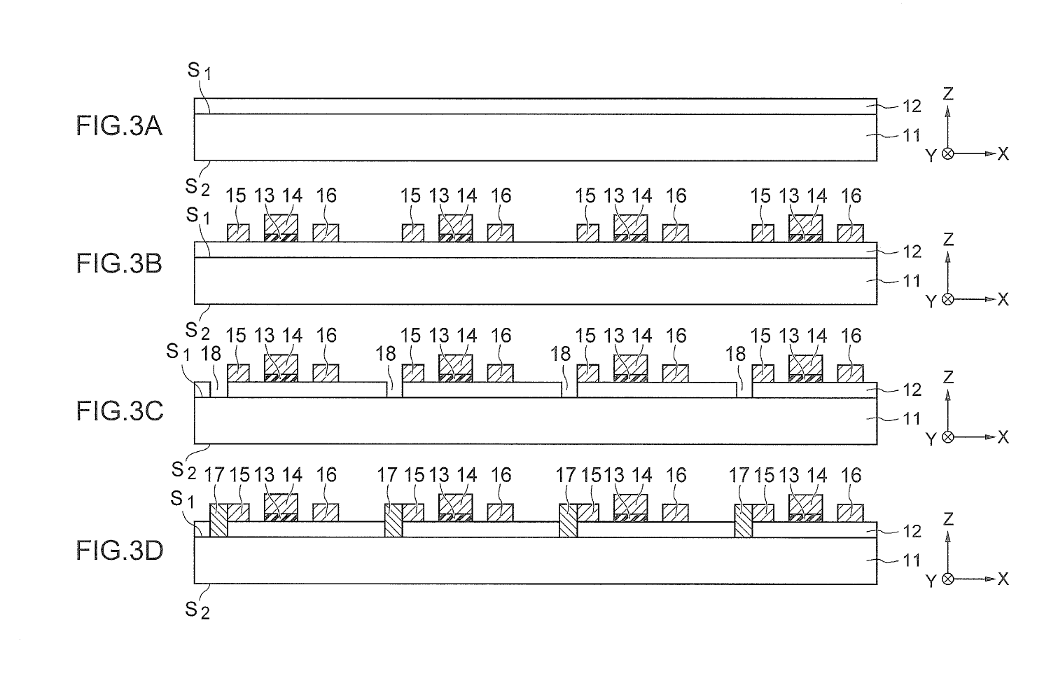

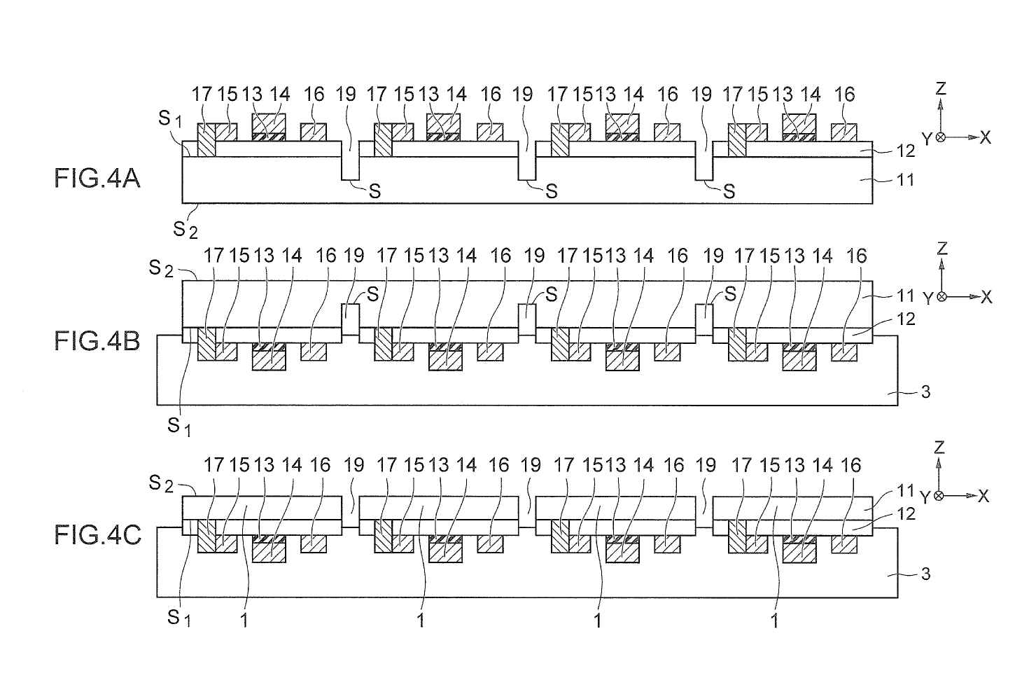

FIGS. 3A to 4C are cross-sectional views illustrating a method of manufacturing the semiconductor device of the first embodiment.

First, as illustrated in FIG. 3A, the nitride semiconductor layer 12 is formed on the first face S₁ of the semiconductor substrate 11.

Next, as illustrated in FIG. 3B, plural sets of the gate insulator 13, the gate electrode 14, the source electrode 15 and the drain electrode 16 are formed on the first face S₁ of the semiconductor substrate 11 via the nitride semiconductor layer 12. FIG. 3B illustrates four sets of the gate insulator 13, the gate electrode 14, the source electrode 15 and the drain electrode 16.

As illustrated in FIG. 3C, plural holes 18 that penetrate the nitride semiconductor layer 12 are formed at positions adjacent to the source electrodes 15. The holes 18 are formed by reactive ion etching (RIE), for example.

As illustrated in FIG. 3D, the post electrodes 17 are formed in the holes 18. As a result, the source electrodes 15 are electrically connected to the semiconductor substrate 11 by the post electrodes 17. The post electrodes 17 are formed by a plating method, for example.

The size of the holes 18 of the present embodiment is set such that the post electrodes 17 can be embedded. An example of a planar shape of the holes 18 is a square of 10 μm×10 μm.

As illustrated in FIG. 4A, plural trenches 19 that penetrate the nitride semiconductor layer 12 and reach the semiconductor substrate 11 are then formed. The trenches 19 are formed in such a way as to penetrate the first face S₁ of the semiconductor substrate 11 while not reaching the second face S₂ of the semiconductor substrate 11. Reference signs S denote bottom portions of the trenches 19. The trenches 19 are formed, for example, between a source electrode 15 and a drain electrode 16 that are included in different sets. Specifically, the trenches 19 are formed on dicing lines of the semiconductor substrate 11.

The trenches 19 of the present embodiment are formed by forming the trenches 19 on the nitride semiconductor layer 12 with etching (for example, RIE) and forming the trenches 19 on the semiconductor substrate 11 with a dicer. In other words, in the process of forming the trenches 19 in the present embodiment, the nitride semiconductor layer 12 is processed with etching and the semiconductor substrate 11 is processed with the dicer.

The reasons of forming the trenches 19 by such a method are as below. In general, the nitride semiconductor layer 12 is harder than the semiconductor substrate 11 while the nitride semiconductor layer 12 is thinner than the semiconductor substrate 11 in thickness. Accordingly, when the nitride semiconductor layer 12 is processed with the dicer, there is a possibility that the dicer is broken and the nitride semiconductor layer 12 has an irregular shape. Accordingly, the nitride semiconductor layer 12 is preferably processed with etching. On the other hand, when the semiconductor substrate 11 is processed with the dicer, there is few possibility of the problems described above. Also, when the trenches 19 are formed on the semiconductor substrate 11, using the dicer facilitates forming of better trenches 19 than using etching. Therefore, in the process of forming the trenches 19 in the present embodiment, the nitride semiconductor layer 12 is processed with etching and the semiconductor substrate 11 is processed with the dicer.

However, when the above problems can be avoided, both of the nitride semiconductor layer 12 and the semiconductor substrate 11 may be processed with the dicer. For example, it is considered to avoid the above problems by processing the nitride semiconductor layer 12 carefully with the dicer, or by using a high-performance dicer to process the nitride semiconductor layer 12 and the semiconductor substrate 11. In such a case, the wasteful processes for processing the nitride semiconductor layer 12 and the semiconductor substrate 11 in different manners can be eliminated.

As illustrated in FIG. 4B, the semiconductor substrate 11 is then attached to a tape 3 while the gate electrodes 14, the source electrodes 15 and the drain electrodes 16 face the tape 3. As a result, the semiconductor substrate 11 is attached to the tape 3 in a face-down state.

As illustrated in FIG. 4C, the semiconductor substrate 11 is then thinned from the second face S₂. The semiconductor substrate 11 is thinned, for example, by chemical mechanical polishing (CMP). The semiconductor substrate 11 is thinned until the second face S₂ of the semiconductor substrate 11 reaches the trenches 19. As a result, the semiconductor substrate 11 is divided into plural semiconductor chips 1.

After that, each semiconductor chip 1 is attached to a support 2 with the solders 25 to 27 as illustrated in FIG. 1. In this way, the semiconductor device of the present embodiment is manufactured.

As described above, the semiconductor device of the present embodiment is manufactured by “dicing before grinding” in which the semiconductor substrate 11 is thinned after the trenches 19 penetrating the nitride semiconductor layer 12 and reaching the semiconductor substrate 11 are formed.

Accordingly, the present embodiment can reduce the dicing time for manufacturing the semiconductor device because it is not necessary to continue dicing until the trenches 19 penetrate the semiconductor substrate 11.

In general, as the dicing depth of the semiconductor substrate 11 becomes deeper, it is necessary to secure the margin of the dicing lines (chipping regions) more widely. The present embodiment can reduce the margin of the dicing lines because the dicing depth of the semiconductor substrate 11 can be reduced.

As described above, the semiconductor chip 1 of the present embodiment is provided on the support 2 such that the gate electrode 14, the source electrode 15 and the drain electrode 16 face the support 2. Furthermore, the gate electrode 14, the source electrode 15 and the drain electrode 16 of the semiconductor chip 1 of the present embodiment are electrically connected to the gate terminal 22, the source terminal 23, and the drain terminal 24 of the support 2, respectively.

Accordingly, the present embodiment makes it possible to electrically connect the gate electrode 14, the source electrode 15 and the drain electrode 16 to the gate terminal 22, the source terminal 23 and the drain terminal 24 respectively without using bonding wires. This can improve the electric conductivity or the thermal conductivity at these connecting portions.

For example, the present embodiment can readily supply a large current and a high voltage to the semiconductor device, and can readily release the heat of the semiconductor device from the gate terminal 22, the source terminal 23 and the drain terminal 24.

Furthermore, the semiconductor device of the present embodiment includes the post electrodes 17 that electrically connects the semiconductor substrate 11 to the source electrodes 15. Accordingly, the present embodiment makes it possible, by preventing the potential of the semiconductor substrate 11 from getting into a floating state with the post electrodes 17, to suppress the collapse of the semiconductor chip 1 due to the lattice mismatch between the semiconductor substrate 11 and the nitride semiconductor layer 12.

The semiconductor substrate 11 of the present embodiment may be a semiconductor substrate other than an Si substrate. An example of such a semiconductor substrate is a silicon carbide (SIC) substrate. The semiconductor substrate 11 of the present embodiment may be replaced by an insulating substrate. An example of such an insulating substrate is a sapphire substrate.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

1. A semiconductor device comprising:
a semiconductor chip including a nitride semiconductor layer, and including a control electrode, a first electrode and a second electrode provided on the nitride semiconductor layer; and
a support including a substrate, and including a control terminal, a first terminal and a second terminal provided on the substrate,
wherein
the semiconductor chip is provided on the support such that the control electrode, the first electrode and the second electrode face the support, and
the control electrode, the first electrode and the second electrode of the semiconductor chip are electrically connected to the control terminal, the first terminal and the second terminal of the support, respectively.

2. The device of claim 1, wherein each of the control terminal, the first terminal and the second terminal includes:
a first portion provided on a first face of the substrate;
a second portion provided on a second face of the substrate; and
a third portion electrically connecting the first portion to the second portion.

3. The device of claim 1, wherein the semiconductor chip includes one or more electrodes electrically connecting the substrate to the first or second electrode.

4. The device of claim 3, wherein
the control electrode, the first electrode and the second electrode have shapes extending in a first direction, and
the one or more electrodes include plural electrodes placed on a straight line parallel to the first direction.

5. The device of claim 4, wherein a distance between the plural electrodes in the first direction is larger than a width of the plural electrodes in the first direction.

6. The device of claim 3, wherein
the control electrode is provided between the first electrode and the second electrode, and
the one or more electrodes are provided on an opposite side to the control electrode relative to the first or second electrode.

7. The device of claim 1, wherein the semiconductor chip is bonded to the support with a solder.

8. A semiconductor device comprising:
a substrate;
a nitride semiconductor layer provided on the substrate;
a control electrode, a first electrode and a second electrode provided on the nitride semiconductor layer; and
one or more electrodes electrically connecting the substrate to the first or second electrode.

9. The device of claim 8, wherein
the control electrode, the first electrode and the second electrode have shapes extending in a first direction, and
the one or more electrodes include plural electrodes placed on a straight line parallel to the first direction.

10. The device of claim 9, wherein a distance between the plural electrodes in the first direction is larger than a width of the plural electrodes in the first direction.

11. The device of claim 8, wherein
the control electrode is provided between the first electrode and the second electrode, and
the one or more electrodes are provided on an opposite side to the control electrode relative to the first or second electrode.

12. A method of manufacturing a semiconductor device, comprising:
forming a nitride semiconductor layer on a first face of a substrate;
forming plural sets of a control electrode, a first electrode and a second electrode on the nitride semiconductor layer;
forming plural trenches which penetrate the nitride semiconductor layer and reach the substrate; and
dividing the substrate into plural semiconductor chips by thinning the substrate from a second face of the substrate until the second face reaches the trenches.

13. The method of claim 12, wherein the trenches are formed by forming the trenches on the nitride semiconductor layer with etching and forming the trenches on the substrate with a dicer.

14. The method of claim 12, wherein the trenches are formed by forming the trenches on the nitride semiconductor layer and the substrate with a dicer.

15. The method of claim 12, further comprising forming one or more electrodes electrically connecting the first or second electrode to the substrate.

16. The method of claim 15, wherein
the control electrode, the first electrode and the second electrode are formed to extend in a first direction, and
the one or more electrodes include plural electrodes placed on a straight line parallel to the first direction.

17. The method of claim 16, wherein a distance between the plural electrodes in the first direction is set larger than a width of the plural electrodes in the first direction.

18. The method of claim 15, wherein
the control electrode is formed between the first electrode and the second electrode, and
the one or more electrodes are formed on an opposite side to the control electrode relative to the first or second electrode.

19. The method of claim 12, further comprising attaching each semiconductor chip to a support such that the control electrode, the first electrode and the second electrode of each semiconductor chip are electrically connected to the control terminal, the first terminal and the second terminal of the support, respectively.

20. The method of claim 19, wherein each semiconductor chip is bonded to the support with a solder.
